(19) United States
(12) Patent Application Publication
(10) Pub. No.: US 2007/0212796 A1
(43) Pub. Date: Sep. 13, 2007

(54) METHOD FOR MANUFACTURING FERROELECTRIC MEMORY DEVICE AND FERROELECTRIC MEMORY DEVICE

(75) Inventor: Mamoru MIYAJI, Kuwana (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/680,809

(22) Filed: Mar. 1, 2007

(30) Foreign Application Priority Data
Mar. 9, 2006 (JP) 2006-064010

(51) Int. Cl. H01L 21/00

(52) U.S. Cl. 438/3

(57) ABSTRACT

A method for manufacturing a ferroelectric capacitor includes the steps of: forming a ferroelectric capacitor having at least a lower electrode, a ferroelectric film and an upper electrode on a base substrate; and applying an anneal treatment to the ferroelectric capacitor in an oxygen atmosphere, wherein the step of forming the ferroelectric capacitor includes forming the ferroelectric capacitor to have a structure in which an electrode protection film composed of titanium oxide is provided on the upper electrode.

The entire disclosure of Japanese Patent Application No. 2006-064010, filed Mar. 9, 2006 is expressly incorporated by reference herein.

### BACKGROUND

1. Technical Field

The present invention relates to ferroelectric memory devices having ferroelectric capacitors and methods for manufacturing the same.

2. Related Art

A ferroelectric memory device (FeRAM) is composed with ferroelectric capacitors, and is a nonvolatile memory that is capable of low voltage and high speed operations (see, for example, Japanese laid-open patent application JP-A-2005-277315). In such a ferroelectric memory device, its memory cell can be composed of, for example, one transistor and one capacitor (1T/1C), whereby integration to the level of DRAM is possible. Accordingly, ferroelectric memory devices are highly expected as large capacity nonvolatile memories in recent years.

For such ferroelectric memory devices, it has become an important issue to prevent deterioration of ferroelectric films in their manufacturing process. In other words, during the process for manufacturing a ferroelectric memory device, after a ferroelectric film is formed, the ferroelectric film may be exposed to a hydrogen atmosphere (i.e., a reducing atmosphere) in the steps of forming an interlayer dielectric film, dry etching and the like. Because the ferroelectric film is generally composed of metal oxide, oxygen that composes the ferroelectric film is reduced when the ferroelectric film is exposed to a reducing atmosphere, such as, for example, hydrogen (H₂), water (H₂O) and the like, and electrical characteristics of the ferroelectric capacitor are considerably deteriorated. As a measure to prevent hydrogen damage, after a capacitor is formed, an insulation film (AlOx film, etc.) having a hydrogen barrier function and covering the capacitor is provided as a hydrogen barrier film.

Also, a ferroelectric capacitor in such a ferroelectric memory device is formed from a lower electrode, a ferroelectric film and an upper electrode. When the ferroelectric capacitor is formed, normally, a layer composed of a material for the lower electrode, a layer composed of a ferroelectric material, and a layer composed of a material for the upper electrode are successively laminated, and these layers are etched and patterned together.

When the ferroelectric capacitor is formed through etching, its ferroelectric film may be damaged. In order to remove the damage and recover the characteristics, a so-called recovery annealing is conducted after forming the ferroelectric capacitor, in which the ferroelectric capacitor is heat-treated in an oxygen atmosphere at about 300° C.-500° C. However, such a heat-treatment (recovery annealing) forms hillocks at the upper electrode that is composed of, for example, iridium (Ir). This phenomenon is believed to occur as compressive stress is generated in the upper electrode by the heat treatment, and metal atoms in the material composing the upper electrode diffuse in order to relieve the stress.

When hillocks are formed on the upper electrode in this manner, when a hydrogen barrier film is formed to cover the ferroelectric capacitor, the hydrogen barrier film cannot be formed well on the upper electrode that has the hillocks formed thereon, and the upper electrode cannot be sufficiently covered by the hydrogen barrier film, such that the ferroelectric capacitor would eventually be deteriorated by hydrogen. In other words, because concave and convex portions are formed by the hillocks, the hydrogen barrier film material would not be deposited particularly in a portion shaded by the convex portion, such that the film would not be formed in such a portion.

Also, contacts that are connected to the lower electrode and the upper electrode of the ferroelectric capacitor are formed, and the ferroelectric capacitor is driven through these contacts and electrodes. In this structure, in particular, the contact that is connected to the upper electrode is formed with a plug that is embedded in a contact hole formed in an interlayer dielectric film that covers the ferroelectric capacitor. When forming the contact hole by etching to reach the upper electrode, it would be difficult to form the contact hole securely in a manner to reach the upper electrode if the hydrogen barrier film that covers the upper electrode is composed of a material that is difficult to be etched. Accordingly, currently, excessive over-etching is conducted to form a contact hole so as to reach an upper electrode. However, by so doing, the upper electrode may be largely cut in part, which leads to degradation of the characteristics of the ferroelectric capacitor.

### SUMMARY

In accordance with an advantage of some aspects of the invention, it is possible to provide a ferroelectric memory device and a method for manufacturing a ferroelectric memory device, in which deterioration of characteristics of a ferroelectric capacitor due to generation of hillocks can be prevented, and formation of a contact hole to reach an upper electrode is facilitated, thereby further preventing degradation of the characteristics of the ferroelectric capacitor.

A method for manufacturing a ferroelectric capacitor in accordance with an embodiment of the invention includes the steps of: forming a ferroelectric capacitor having at least a lower electrode, a ferroelectric film and an upper electrode on a base substrate; and applying an anneal treatment to the ferroelectric capacitor in an oxygen atmosphere, wherein, in the step of forming the ferroelectric capacitor, the ferroelectric capacitor is formed to have a structure in which an electrode protection film composed of titanium oxide is provided on the upper electrode.

According to the method for manufacturing a ferroelectric memory device, the ferroelectric capacitor is formed in a structure in which an electrode protection film composed of titanium oxide is provided on the upper electrode. Therefore, when an anneal treatment is applied later to the ferroelectric capacitor in an oxygen atmosphere, the electrode protection film suppresses generation of hillocks on the surface of the upper electrode, whereby deterioration of characteristics of the ferroelectric capacitor can be prevented. In other words, even when metal atoms in the material composing the upper electrode diffuse at the time of the anneal treatment, the diffusing atoms remain within the electrode protection film because the electrode protection film composed of titanium oxide is provided on the upper electrode, such that generation of hillocks can be prevented.

Also, the method for manufacturing a ferroelectric memory device may preferably include, after the step of applying an anneal treatment, the step of forming a hydrogen barrier film that covers the ferroelectric capacitor including the electrode protection film.

Generation of hillocks is suppressed by the electrode protection film, and therefore the top surface of the ferroelectric capacitor forms a flat surface without irregularities, such that, by forming the hydrogen barrier film thereon, the hydrogen barrier film is favorably coated on the upper electrode, in other words, on the electrode protection film. Accordingly, deterioration of characteristics of the ferroelectric capacitor that may be caused by hydrogen and the like can be securely prevented by the hydrogen barrier film.

Also, the method for manufacturing a ferroelectric memory device may preferably include, after the step of applying an anneal treatment, the steps of forming an interlayer dielectric film that covers the ferroelectric capacitor including the electrode protection film over the base substrate, and forming a contact hole in the interlayer dielectric film by etching which reaches the upper electrode of the ferroelectric capacitor.

For forming a contact hole that reaches the upper electrode, excessive over-etching may have been needed in the past, for example, when the upper electrode is covered by a hydrogen barrier film composed of a material that is difficult to be etched. In contrast, according to the manufacturing method of the present embodiment, the electrode protection film is provided on the upper electrode. The electrode protection film functions as an etching stopper layer, the etching is substantially slowed down and the etching is apparently almost stopped by the electrode protection film even in excessive etching, whereby the etching is facilitated. Accordingly, thereafter, etching may be conducted for the electrode protection film if necessary, whereby the contact hole can be formed without largely cutting the upper electrode in part. Therefore, deterioration of characteristics of the ferroelectric capacitor can be prevented.

Furthermore, the method for manufacturing a ferroelectric memory device may preferably include, after the step of forming a contact hole, the step of cleansing inside the contact hole by dry etching or the like.

By so doing, residues of the electrode protection film and its reactants remaining in the contact hole can be removed, such that electrical conduction between the plug embedded in the contact hole and the upper electrode can be made more secure, and the connection resistance can be lowered.

Also, in the method for manufacturing a ferroelectric memory device, the step of forming the ferroelectric capacitor above the base substrate may preferably include the steps of: forming at least a lower electrode layer, a ferroelectric layer, an upper electrode layer and a titanium oxide layer on the base substrate; patterning the titanium oxide layer on the upper electrode layer by high-temperature etching between 200° C. and 500° C. into a mask pattern; and etching the upper electrode layer, the ferroelectric layer and the lower electrode layer together by using the mask pattern as a mask, to thereby form a ferroelectric capacitor having a lower electrode, a ferroelectric film, an upper electrode and an electrode protection film composed of the mask pattern.

Because titanium oxide such as titania (TiO₂) is difficult to be etched, and is therefore difficult to be patterned, it was thought that titanium oxide could not be used as a hard mask. However, it has discovered that titanium oxide has a moderate etching rate in high-temperature etching at about 200° C., and can therefore be patterned and used as a hard mask. Accordingly, etching is conducted by using titanium oxide that is difficult to be etched and therefore has great etching resistance as a mask pattern to form the ferroelectric capacitor, whereby the mask pattern composed of titanium oxide can be made relatively thin. Accordingly, the aspect ratio of the mask to be used for forming the ferroelectric capacitor is relatively lowered, and the ferroelectric capacitor can be etched favorably to its bottom side without conducting excessive over-etching. As a consequence, problems as such roughened side wall surfaces of the ferroelectric capacitor that may be caused by excessive over-etching, and the resultant difficulty to obtain good ferroelectric characteristics can be avoided.

Moreover, the mask pattern is formed by patterning a titanium oxide layer in high-temperature etching between 200° C. and 500° C. Therefore, although titanium oxide is difficult to be etched at room temperature as described above, it can be patterned by etching particularly when it is conducted at 200° C. or higher. Also, since the etching is conducted at 500° C. or below, other components such as a driving transistor for driving the ferroelectric capacitor to be obtained can be prevented from being thermally damaged.

In the method for manufacturing a ferroelectric memory device, the step of forming the mask pattern on the upper electrode layer may preferably include the steps of: forming a second mask pattern on the titanium oxide layer, and etching the titanium oxide layer in high-temperature etching by using the second mask pattern to thereby form a mask pattern, wherein the step of forming the ferroelectric capacitor may preferably be conducted by etching and patterning, using a laminated mask pattern composed of the mask pattern and the second mask pattern as a mask.

As a result, etching is conducted by using the laminated mask pattern composed of the mask pattern and the second mask pattern, such that the burden on the mask pattern composed of titanium oxide is reduced, and the film thickness thereof can be made smaller. Accordingly, etching of the titanium oxide layer that is difficult to be etched can be reduced to a necessity minimum.

In the method for manufacturing a ferroelectric memory device, the step of forming the ferroelectric capacitor over the base substrate may preferably include forming the ferroelectric capacitor in a structure in which an oxygen barrier film is provided between the base substrate and the lower electrode.

Because the oxygen barrier film is provided between the base substrate and the lower electrode, oxidation of a plug in a contact hole formed in the base substrate and the resultant substantial increase in the resistance in the anneal treatment step conducted in an oxygen atmosphere after forming the ferroelectric capacitor can be prevented. Accordingly, electrical conductivity between the plug and the lower electrode can favorably be secured.

A ferroelectric memory device in accordance with an embodiment of the invention includes: a base substrate; a lower electrode, a ferroelectric film and an upper electrode provided on a base substrate; an electrode protection film composed of titanium oxide provided on the upper electrode, wherein the lower electrode, the ferroelectric film, the upper electrode and the electrode protection film form a ferroelectric capacitor on the base substrate; and a hydrogen barrier film that covers the ferroelectric capacitor.

According to the ferroelectric memory device described above, the ferroelectric capacitor is formed with the electrode protection film composed of titanium oxide provided on the upper electrode. Therefore, when an anneal treatment is applied to the formed ferroelectric capacitor in an oxygen atmosphere at the time of manufacturing, the electrode protection film suppresses generation of hillocks on the surface of the upper electrode, whereby deterioration of the characteristic of the ferroelectric capacitor can be prevented. Also, the top surface of the ferroelectric capacitor is in a flat surface without irregularities, such that the hydrogen barrier film is favorably coated on the upper electrode. Accordingly, deterioration of characteristics of the ferroelectric capacitor that may be caused by hydrogen and the like can be securely prevented by the hydrogen barrier film.

Also, in the ferroelectric memory device, an interlayer dielectric film that covers the hydrogen barrier film may preferably be provided above the base substrate, and a contact hole that is connected to the upper electrode of the ferroelectric capacitor may be formed in the interlayer dielectric film.

With the structure described above, at the time of manufacturing, when a contact hole that reaches the upper electrode is formed, the electrode protection film, which is provided on the upper electrode, functions as an etching stopper layer, and therefore the etching is substantially slowed down and is apparently almost stopped by the electrode protection film even in excessive etching. Accordingly, thereafter, etching may be conducted for the electrode protection film depending on the necessity, whereby the contact hole can be formed without largely cutting the upper electrode in part. Therefore, deterioration of characteristics of the ferroelectric capacitor can be prevented.

### BRIEF DESCRIPTION OF THE DRAWINGS

FIG. 1 is a cross-sectional view in part of a ferroelectric memory device in accordance with an embodiment of the invention.

FIGS. 2A-2C are views for describing steps of a method for manufacturing the device shown in FIG. 1.

FIGS. 3A-3C are views for describing steps of the method for manufacturing the device shown in FIG. 1.

FIGS. 4A and 4B are views for describing steps of the method for manufacturing the device shown in FIG. 1.

FIGS. 5A and 5B are views for describing steps of the method for manufacturing the device shown in FIG. 1.

### DESCRIPTION OF EXEMPLARY EMBODIMENTS

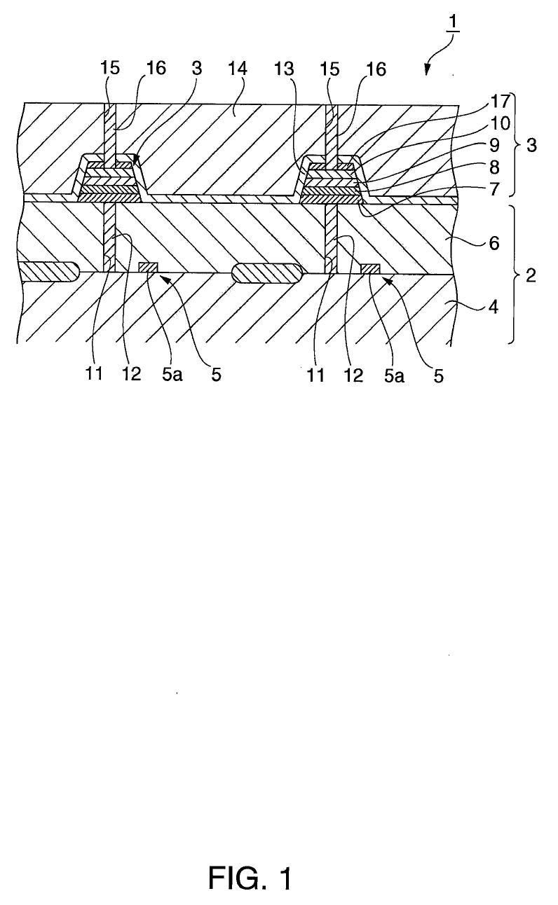

Examples of preferred embodiments of the invention are described below. First, a ferroelectric memory device in accordance with an embodiment of the invention is described. FIG. 1 is a cross-sectional view in part of a ferroelectric memory device in accordance with an embodiment of the invention. Reference numeral 1 in the figure denotes a ferroelectric memory device. The ferroelectric memory device 1 is of a stacked type having a 1T/1C memory cell structure, and is equipped with a base substrate 2, and a plurality of ferroelectric capacitors 3 provided on the base substrate 2.

The base substrate 2 is formed from a silicon substrate (i.e., a semiconductor substrate) 4. Transistors 5 for driving the ferroelectric capacitors 4 are formed on a top surface portion of the silicon substrate 4, and a base dielectric film 6 that covers the driving transistors 5 is formed above the silicon substrate 4. Source and drain regions (not shown) and channel regions (not shown) composing the driving transistors 5 are formed in the silicon substrate 4, and gate dielectric films (not shown) are formed over the channel regions. Further, gate electrodes 5a are formed on the gate dielectric films, thereby forming the driving transistors 5, respectively.

It is noted that the driving transistors 5 corresponding to the respective ferroelectric capacitors 3 are electrically isolated from one another by embedded isolation regions (not shown) formed in the silicon substrate 4. Further, the base dielectric film 6 may be composed of silicon oxide (SiO₂), and planarized by a CMP (chemical mechanical polishing) method or the like.

Over the base substrate 2 where the driving transistors 5 and the base dielectric film 6 are formed on the silicon substrate 4, the ferroelectric capacitors 3 are formed on the base dielectric film 6. Each of the ferroelectric capacitors 3 is composed of an oxygen barrier film 7 formed on the base dielectric film 6, a lower electrode 8 formed on the oxygen barrier film 7, a ferroelectric film 9 formed on the lower electrode 8, an upper electrode 10 formed on the ferroelectric film 9, and an electrode protection film 17.

The oxygen barrier film 7 may be composed of, for example, TiAlN, TiAl, TiSiN, TiN, TaN, TaSiN or the like. Above all, TiAlN including titanium, aluminum and nitrogen is suitable, and the oxygen barrier film 7 is formed from TiAlN in the present example.

The lower electrode 8 and the upper electrode 10 may be formed from, for example, iridium (Ir), iridium oxide (Ir Oₓ), platinum (Pt), ruthenium (Ru), ruthenium oxide (RuOₓ) or the like. In the present example, the lower electrode 8 and the upper electrode 10 are formed from iridium.

The ferroelectric film 9 is composed of material having a perovskite crystal structure, which may be expressed by a general formula, ABXO₃. Concretely, the ferroelectric film 9 is composed of Pb (Zr, Ti)O₃ (PZT), (Pb, La) (Zr, Ti) O₃ (PLZT), or a ferroelectric material in which metal such as niobate (Nb) or the like is added to the foregoing material. In the present embodiment example, the ferroelectric film 9 is formed from PZT.

The electrode protection film 17 is composed of titanium oxide (TiOx) such as titania (TiO₂), and is formed into a thin film of 100 nm or less in thickness.

A bottom portion of the oxygen barrier film 7 is connected to a contact hole 11 formed in a manner to penetrate the base dielectric film 6. With this structure, the lower electrode 8 on the oxygen barrier film 7 is conductively connected to a plug 12 formed in the contact hole 11. The plug 12 is connected to one of the source and drain regions of the driving transistor 5, whereby the ferroelectric capacitor 3 is operated by the driving transistor 5, as described above. It is noted that the plug 12 embedded in the contact hole 11 is formed from tungsten (W) in the present example.

Also, a dielectric hydrogen barrier film 13 that covers the ferroelectric capacitors 3 is formed on the base dielectric film 6. The hydrogen barrier film 13 exhibits a hydrogen barrier function, thereby protecting the ferroelectric film 9 whose electrical characteristics would likely be lowered, particularly, due to the reducing action of hydrogen. As the dielectric hydrogen barrier film 13, aluminum oxide such as alumina (AlOx), titanium oxide such as titania (TiOx), zircon oxide such as zirconia (ZrOx) or the like is used, and in particular, alumina (AlOx) is preferably used. Accordingly, in the present example, the hydrogen barrier film 13 is composed of alumina (AlOx).

An interlayer dielectric film 14 is formed on the hydrogen barrier film 13. The interlayer dielectric film 14 is formed from silicon oxide (SiO₂), like the base dielectric film 6, and planarized by a CMP (chemical mechanical polishing) method or the like. Contact holes 15, which penetrate the interlayer dielectric film 14, further penetrate the hydrogen barrier film 13 and the electrode protection film 17, and connect to the upper electrodes 10, are formed in the interlayer dielectric film 14, and plugs 16 are embedded in the contact holes 15. The ferroelectric capacitors 3 having such a structure as described above are driven by the driving transistors 5 and conductive sections (not shown) connected to the plugs 16, respectively. Further, a second interlayer dielectric film (not shown) that covers the conductive sections may be formed on the interlayer dielectric film 14.

Next, a method for manufacturing a ferroelectric memory device in accordance with an embodiment of the invention is described based on the method for manufacturing the ferroelectric memory device 1 having the structure described above.

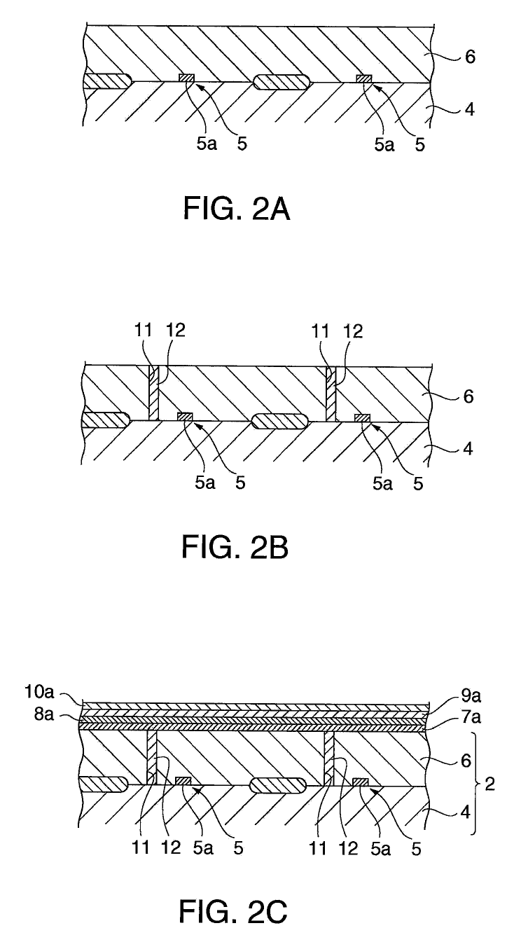

First, as shown in FIG. 2A, driving transistors 5 are formed in advance on a silicon substrate 4 by a known method. Then, a silicon oxide (SiO₂) film is formed by a CVD method or the like, and planarized by a CMP method, thereby forming a base dielectric film 6.

Then, a resist pattern (not shown) is formed on the base dielectric film 6 by known resist technique and exposure and development technique, and etching is conducted by using the resist pattern as a mask, thereby forming contact holes 11, as shown in FIG. 2B.

Then, tungsten (W) as a plug material is formed into a film by a sputter method or the like, whereby the tungsten is embedded in the contact holes 11. Then, portion of the tungsten on the base dielectric film 6 is removed by a CMP method or the like, whereby plugs 12 composed of tungsten are embedded in the contact holes 11. It is noted that, when forming the plugs 12, prior to embedding tungsten, an adhesion layer composed of TiN (titanium nitride) or the like may preferably be formed in a thin film on inner wall surfaces of the contact holes 11 by a sputter method or the like, and then, tungsten is embedded in the contact holes 11, as described above.

Then, for forming ferroelectric capacitors 3 on the base dielectric film 6, first, a forming material of an oxygen barrier film 13 that covers upper surfaces of the plugs 12 is formed on the base dielectric film 6. More concretely, a film of TiAlN is formed by a sputter method or the like, thereby forming an oxygen barrier layer 7a, as shown in FIG. 2C. Then, a film of iridium that is a forming material of a lower electrode 8 is formed on the oxygen barrier layer 7a by a sputter method or the like, thereby forming a lower electrode layer 8a.

Then, a film of PZT that is a forming material of a ferroelectric film 9 is formed on the lower electrode layer 8a by, for example, a sputter method, a spin-on method, a MOCVD method or the like, thereby forming a ferroelectric layer 9a. Then, a film of iridium that is a forming material of an upper electrode 10 is formed on the ferroelectric layer 9a by a sputter method or the like, thereby forming an upper electrode layer 10a. In this manner, the oxygen barrier layer 7a, the lower electrode layer 8a, the ferroelectric layer 9a and the upper electrode layer 10a are laminated, whereby a laminated film substantially composing a ferroelectric capacitor layer 3 in accordance with the present embodiment can be obtained.

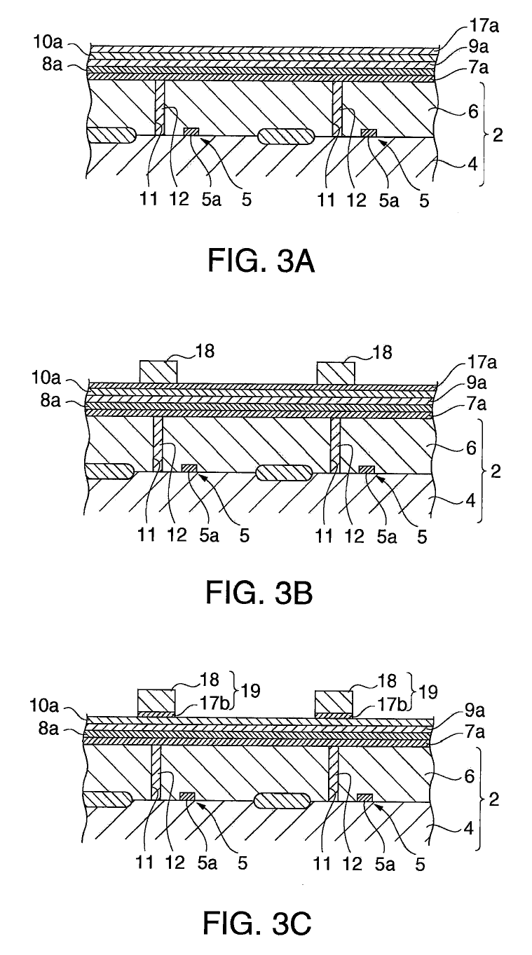

Then, as shown in FIG. 3A, a film of titanium oxide (TiOx such as TiO₂) is formed on the laminated film, in other words, on the upper electrode layer 10a, thereby forming a titanium oxide layer 17a to a thickness of, for example, about 50-100 nm. The titanium oxide layer 17a functions as a mask pattern, after it is patterned to be described below, and becomes to be an electrode protection film 17, as described above. Then, a second mask material is formed on the titanium oxide layer 17a into a film that becomes to be a mask for patterning the titanium oxide layer 17a, thereby forming a second mask material layer (not shown).

It is noted that, as the second mask material that forms the second mask material layer, silicon oxide (SiOx such as SiO₂) may preferably be used. As a method of forming the second mask material layer composed of silicon oxide (a silicon oxide layer), a chemical vapor deposition (CVD) method using tetraethoxysilane (TEOS) as a raw material is particularly suitable. Accordingly, in accordance with the present embodiment, the second mask material layer (a silicon oxide layer) is formed by a CVD method using TEOS as a raw material. Film formation of the silicon oxide layer (the second mask layer) by a CVD method using TEOS as a raw material is a relatively easy film forming method, and the obtained silicon oxide layer can be readily etched, and thus has good workability, such that a second mask pattern can be readily formed from the silicon oxide layer (the second mask material layer), as described below.

Then, a resist pattern (not shown) is formed on the second mask material layer by known resist technique and exposure and development technique, and the second mask material layer is etched by using the resist pattern as a mask, whereby a second mask pattern 18 is formed, as shown in FIG. 3B. It is noted that FIG. 3B shows a state in which, after the second mask pattern 18 has been formed, the resist pattern is removed by ashing or the like.

Then, the titanium oxide layer 17a is etched by high-temperature etching, using the second mask pattern 18 as a mask, thereby forming a mask pattern 17b, as shown in FIG. 3C, which becomes to be an electrode protection film 17, as described above. The high-temperature etching may be conducted in a temperature range between 200° C. and 500° C. in accordance with the present embodiment of the invention, and may preferably be conducted in a temperature range between 350° C. and 450° C. More concretely, the base substrate 2 is set to a retaining section within an etching apparatus (a high-temperature etcher), the base substrate 2 is then heated in the temperature range described above, and etching is conducted. Etching gas may be pre-heated depending on the requirements, and then supplied in the etching apparatus. As the etching method, a reactive ion etching (RIE) method using a single gas of Cl₂, BCl₃, CF₄, C₂F₆ or C₄F₈, or a mixed gas of the aforementioned gas and Ar or He may preferably be used.

The temperature range in the high-temperature etching is set between 200° C. and 500° C., because titanium oxide such as titania (TiO₂) is hardly etched and therefore patterning thereof is substantially difficult at temperatures less than 200° C. However, if the temperature exceeds over 500° C., other components, such as, for example, the driving transistors 5 formed on the base substrate 2 may be thermally damaged, and their characteristics may be negatively affected. In order to prevent the problems described above more securely, and in order to conduct favorable etching without causing thermal damage on the other components, the temperature range is preferably set between 350° C. and 450° C.

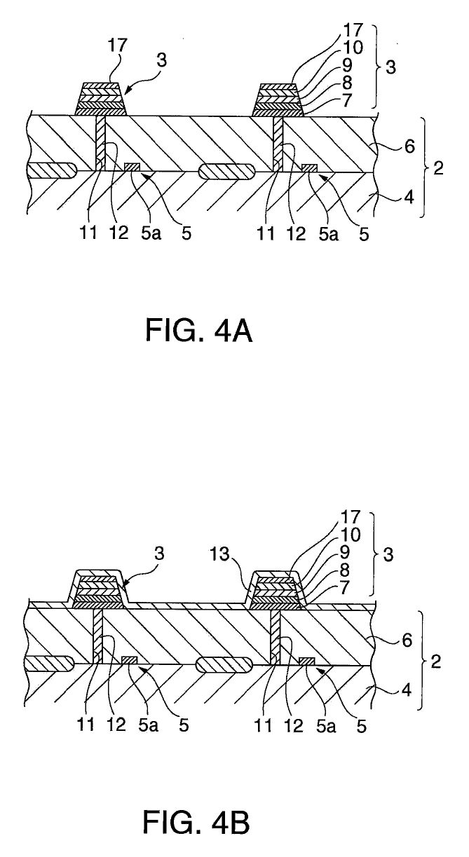

After the mask pattern 17b has been formed in a manner described above, the second mask pattern 18 used for forming the mask pattern 17b is left as it is without being removed, and the mask pattern 18 and the mask pattern 17b are left together as a laminated mask pattern 19. Then, as shown in FIG. 4A, the laminated film is etched and patterned by using the laminated mask pattern 19, thereby forming ferroelectric capacitors 3. It is noted that, in particular, the second mask pattern 18 is removed by dry etching or the like, during or after the patterning. Also, the mask pattern 17b remains on the upper electrode 10, and becomes to be an electrode protection film 17, as described above.

More concretely, in accordance with the present embodiment of the invention, in particular, when the upper electrode layer 10a, the ferroelectric layer 9a and the lower electrode 8a among the laminated film are etched, the etching is stopped once. Then, only the second mask pattern 18 may be selectively removed, and etching is conducted again by using the remaining mask pattern 17 alone, to thereby form the ferroelectric capacitors 3. In this case, for example, after the etching is stopped once, the base substrate 2 may be taken out of the etching apparatus (i.e., a high-temperature etcher) and placed in a dry etcher, where the second mask pattern 18 alone is selectively removed. Then, the base substrate 2 is returned to the high-temperature etcher, where etching is conducted again by using the remaining mask pattern 17 alone as a mask to pattern the oxygen barrier layer 7a, thereby forming the ferroelectric capacitors 3.

It is noted that, in particular, etching of the oxygen barrier layer 7a may be conducted by high-temperature etching, like etching of the titanium oxide layer 17a, such that the mask pattern 17 can be etched, concurrently with patterning (etching) of the oxygen barrier layer 7a. In other words, through concurrently etching the mask pattern 17 in this manner, patterning of the oxygen barrier layer 7a is completed, and when the ferroelectric capacitor 3 is obtained, the mask pattern 17 has been etched to a degree, whereby its film thickness is adjusted to a predetermined thickness. The adjustment of film thickness can be conducted through appropriately setting in advance the thicknesses of the oxygen barrier layer 7a and the mask pattern 17 to specified values, etching conditions and the like based on experiments and the like.

In the case of etching that uses the laminated mask pattern 19 as a mask, the total thickness of the laminated mask pattern 19 would become smaller compared with a conventional mask pattern, as the mask pattern 17 composed of titanium oxide is particularly thin, which is about 50-100 nm. As a result, the aspect ratio becomes lower, and etching of the laminated film to the side of its bottom portion (the lower electrode layer 8a) can be favorably conducted. Further, in particular, as the oxygen barrier layer 7a is also patterned by using the mask pattern 17, the ferroelectric capacitors 3 can be favorably formed without conducting excessive over-etching.

When the ferroelectric capacitors 3 are formed through patterning in a manner described above, the ferroelectric film 9 is damaged by etching. Accordingly, to remove the damage and recover the characteristics, heat treatment is conducted in an oxygen atmosphere between about 300° C. and about 500° C., and more preferably about 350° C., in other words, so-called recovery annealing is conducted. Because the electrode protection film 17 composed of titanium oxide is provided on the upper electrodes 10 of the ferroelectric capacitors 3, generation of hillocks at the surface of the upper electrodes 10 is suppressed by the electrode protection film 17. In other words, even when metal atoms (for example, Ir) in the material composing the upper electrodes 10 diffuse at the time of the anneal treatment, the diffusing atoms remain within the electrode protection film 17 because the electrode protection film 17 is provided on the upper electrodes 10, such that generation of hillocks can be prevented. Accordingly, the top surface of the ferroelectric capacitors 3, in other words, the top surface of the electrode protection film 17, becomes flat, without forming irregularities by hillocks.

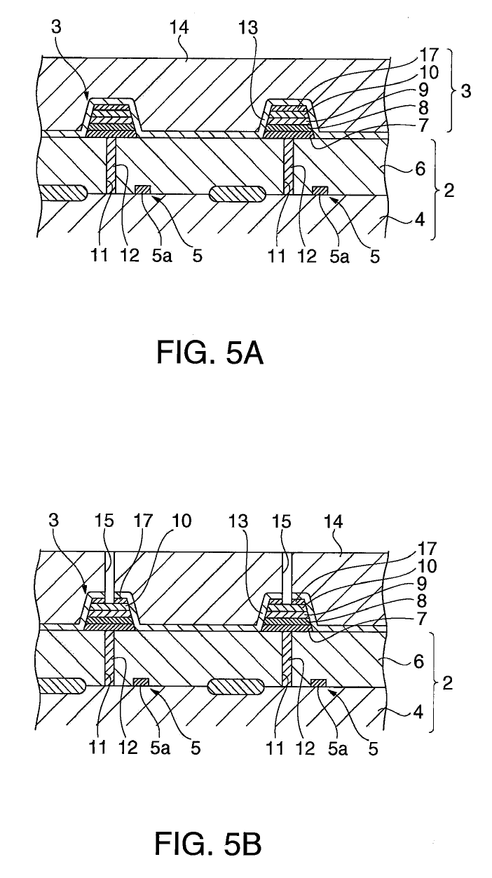

Then, as shown in FIG. 4B, AlOx that covers the obtained ferroelectric capacitors 3 is deposited in a film by a sputter method, a CVD method or the like over the base dielectric film 6, thereby forming a hydrogen barrier film 13. As described above, the top surface of the electrode protection film 17 forms a flat surface. Therefore, by forming the hydrogen barrier film 13 thereon, the hydrogen barrier film 13 favorably covers the upper electrodes 10, in other words, the electrode protection film 17. Then, a film of silicon oxide (SiO₂) is formed on the formed hydrogen barrier film 13 by a CVD method or the like, and further planarized by a CMP method or the like, thereby forming an interlayer dielectric film 14, as shown in FIG. 5A.

Next, a resist pattern (not shown) is formed on the interlayer dielectric film 14 by known resist technique and exposure and development technique, and the interlayer dielectric film 14 is etched by using the resist pattern as a mask, thereby forming contact holes 15 that connect to the upper electrodes 10, as shown in FIG. 5B. In this instance, the hydrogen barrier film 13 is composed of AlOx that is a material difficult to be etched, compared with the interlayer dielectric film 14 that is composed of silicon oxide (SiO₂). Therefore, in order to penetrate the hydrogen barrier film 13 by etching, over-etching needs to be conducted with relatively excessive conditions compared to those for etching an apparent thickness.

In the past, the upper electrode 10 would be largely cut in part by such excessive over-etching, which resulted in deterioration of the characteristics of the ferroelectric capacitor. In contrast, in accordance with the present embodiment of the invention, because the electrode protection film 17 is provided on the upper electrode 10, the upper electrode 10 is prevented from being largely cut in portion, and deterioration of characteristics of the ferroelectric capacitor 3 can be prevented. In other words, the electrode protection film 17 functions as an etching stopper layer, such that, even when etching is conducted with relatively excessive conditions compared to those that may be required for etching an apparent thickness, the etching is considerably slowed down, and the etching apparently almost stops at the electrode protection film 17.

However, as described above, as the electrode protection film 17 is extremely thin, which is, for example, 50 nm-100 nm, it is eventually penetrated after a certain time elapses, though the etching is apparently almost stopping. Accordingly, the time required for the electrode protection film 17 to be penetrated may be obtained in advance by experiments or the like, and the etching time is accordingly controlled, so that etching is set to be finished at the time when the electrode protection film 17 is penetrated and the upper electrode 10 is exposed. It is noted that, as the etching advances considerably slowly at the electrode protection film 17, a large margin can be taken for etching completion time, and therefore the control of etching time becomes easier.

Also, at the time of setting the etching time, if the etching time is adjusted such that the etching lasts for a long time after the upper electrode 10 is exposed, there is a possibility that the upper electrode 10 may be largely cut. Therefore, the etching time is preferably adjusted such that the etching is finished before the upper electrode 10 is completely exposed.

If the upper electrode 10 is not completely exposed in a manner described above, and a portion of the electrode protection film 17 therefore remains within the formed contact hole 15, the contact hole 15 may preferably be cleansed by a cleansing treatment after forming the contact hole 15. As the cleansing treatment, etching with Ar (reverse sputter with Ar) gas, which is generally conducted as a pretreatment prior to forming an adhesion layer, or a cleansing treatment by dry etching with another kind of gas may be conducted as it is for both purposes.

More specifically, after forming a contact hole, and before embedding a plug in the contact hole, an adhesion layer composed of TiN or the like is generally formed in advance. Before forming the adhesion layer, the cleansing treatment described above can be conducted, whereby a conduction section (the upper electrode 10 in this example) is sufficiently exposed within the contact hole. Accordingly, in accordance with the present embodiment, such a cleansing treatment can be conducted, whereby a portion of the electrode protection film 17 remaining within the contact hole 15 is securely removed, and the upper electrode 10 can be sufficiently exposed within the contact hole 15.

After conducting the cleansing treatment in this manner, an adhesion layer (not shown) composed of TiN or the like is thinly formed on the inner wall surface of the contact holes 15, and then, plugs 16 are embedded in the contact holes 15, as shown in FIG. 1. Further, conduction sections (not shown) such as wirings that are conductively connected to the plugs 16 are formed, and a second interlayer dielectric film (not shown) that covers the aforementioned layers and wirings is formed, whereby the ferroelectric memory device 1 in accordance with the present embodiment is obtained.

According to the method for manufacturing the ferroelectric memory device 1, the ferroelectric capacitor 3 is formed with the electrode protection film 17 composed of titanium oxide provided on the upper electrode 10. Therefore, when the ferroelectric capacitor 3 is subjected to an anneal treatment in an oxygen atmosphere, the electrode protection film 17 suppresses generation of hillocks on the surface of the upper electrode 10. Accordingly, the top surface of the ferroelectric capacitor 3, in other words, the top surface of the electrode protection film 17 has a flat surface without forming irregularities due to hillocks, such that, when the hydrogen barrier film 13 is formed thereon, the hydrogen barrier film 13 favorably covers the upper electrode 10, in other words, the electrode protection film 17. Therefore, deterioration of characteristics of the ferroelectric capacitor 3, which may be caused by hydrogen or the like, can be securely prevented by the hydrogen barrier film 13.

Also, because the electrode protection film 17 is provided on the upper electrode 10, the electrode protection film 17 functions as an etching stopper layer, such that, even when excessive etching is conducted, the etching is considerably slowed down, and the etching apparently almost stops at the electrode protection film 17, which facilitates the etching process. Accordingly, thereafter, etching for the electrode protection film 17 and cleansing of the inside of the contact hole 15 may be conducted if necessary, whereby the contact hole 15 can be formed without largely cutting the upper electrode 15 in part. Therefore, deterioration of characteristics of the ferroelectric capacitor 3 can be prevented.

Furthermore, the mask pattern 17b composed of titanium oxide that is difficult to be etched and thus has large etching resistance is laminated with the second mask pattern 18 to form the laminated mask pattern 19, and etching is conducted using the laminated mask pattern 19 to pattern the ferroelectric capacitor 3. As a result, the aspect ratio of the masks at the time of forming the ferroelectric capacitor 3 can be made relatively low, and therefore the ferroelectric capacitor 3 can be favorably etched to the side of its bottom portion. As a consequence, the workability at the time of forming the ferroelectric capacitors 3 can be improved, and excessive over-etching can be made unnecessary, such that side wall surfaces of the ferroelectric capacitors 3 can be prevented from being roughened due to excessive over-etching, and the ferroelectric capacitors 3 with excellent ferroelectric characteristics can be formed.

Also, etching is conducted by using the laminated mask pattern 19 composed of the mask pattern 17 and the second mask pattern 18 as a mask, such that the burden on the mask pattern 17b composed of titanium oxide is lessened and the film thickness thereof can be made smaller, and therefore etching for the titanium oxide layer that is difficult to be etched can be suppressed to a necessity minimum.

Also, in the ferroelectric memory device obtained in a manner described above, the hydrogen barrier film 13 favorably covers the top surface of the ferroelectric capacitor 3, such that deterioration of characteristics of the ferroelectric capacitor 3, which may be caused by hydrogen or the like, can be securely prevented by the hydrogen barrier film 13. Furthermore, the contact hole 15 is formed without largely cutting the upper electrode 10 in part, such that deterioration of characteristics of the ferroelectric capacitor 3 can be prevented.

It is noted that the ferroelectric memory device 1 is applicable to various electronic devices, such as, for example, cellular phones, personal computers, liquid crystal devices, electronic notebooks, pagers, POS terminals, IC cards, mini-disc players, liquid crystal projectors, engineering workstations (EWS), word processors, televisions, view finder or monitor-direct viewing type video recorders, electronic desk-top calculators, car-navigation systems, devices equipped with touch-panels, clocks, gaming devices, and electrophoretic devices.

Also, the invention is not limited to the embodiments described above, and many changes can be made without departing from the subject matter of the invention. For example, in the embodiment described above, the laminated film is etched by using the laminated mask pattern 19 composed of the mask pattern 17b and the second mask pattern 18 as a mask. However, the laminated film may be etched and patterned by using only the mask pattern 17 composed of titanium oxide as a mask.

What is claimed is:

1. A method for manufacturing a ferroelectric capacitor, comprising the steps of:
forming a ferroelectric capacitor having at least a lower electrode, a ferroelectric film and an upper electrode on a base substrate; and
applying an anneal treatment to the ferroelectric capacitor in an oxygen atmosphere,
wherein the step of forming the ferroelectric capacitor includes forming the ferroelectric capacitor to have a structure in which an electrode protection film composed of titanium oxide is provided on the upper electrode.

2. A method for manufacturing a ferroelectric memory device according to claim 1, comprising, after the step of applying an anneal treatment, the step of forming a hydrogen barrier film that covers the ferroelectric capacitor including the electrode protection film.

3. A method for manufacturing a ferroelectric memory device according to claim 1, comprising, after the step of applying an anneal treatment, the steps of forming an interlayer dielectric film that covers the ferroelectric capacitor including the electrode protection film over the base substrate, and forming a contact hole in the interlayer dielectric film by etching which reaches the upper electrode of the ferroelectric capacitor.

4. A method for manufacturing a ferroelectric memory device according to claim 3, comprising, after the step of forming a contact hole, the step of cleansing inside the contact hole.

5. A method for manufacturing a ferroelectric memory device according to claim 1, wherein the step of forming the ferroelectric capacitor above the base substrate includes the steps of:
forming at least a lower electrode layer, a ferroelectric layer, an upper electrode layer and a titanium oxide layer on the base substrate;
patterning the titanium oxide layer on the upper electrode layer by high-temperature etching between 200° C. and 500° C. into a mask pattern; and
etching the upper electrode layer, the ferroelectric layer and the lower electrode layer together by using the mask pattern as a mask, to thereby form a ferroelectric capacitor having a lower electrode, a ferroelectric film, an upper electrode and an electrode protection film composed of the mask pattern.

6. A method for manufacturing a ferroelectric memory device according to claim 5, wherein the step of forming the mask pattern on the upper electrode layer includes the steps of forming a second mask pattern on the titanium oxide layer, and etching the titanium oxide layer in high-temperature etching by using the second mask pattern to thereby form a mask pattern,
wherein the step of forming the ferroelectric capacitor includes etching and patterning, by using a laminated mask pattern composed of the mask pattern and the second mask pattern as a mask.

7. A method for manufacturing a ferroelectric memory device according to claim 1, wherein the step of forming the ferroelectric capacitor over the base substrate includes forming the ferroelectric capacitor in a structure in which an oxygen barrier film is provided between the base substrate and the lower electrode.

8. A ferroelectric memory device comprising:
a base substrate;
a lower electrode, a ferroelectric film and an upper electrode provided on a base substrate;
an electrode protection film composed of titanium oxide provided on the upper electrode, whereby the lower electrode, the ferroelectric film, the upper electrode and the electrode protection film form a ferroelectric capacitor on the base substrate; and
a hydrogen barrier film that covers the ferroelectric capacitor.

9. A ferroelectric memory device according to claim 8, comprising an interlayer dielectric film that covers the hydrogen barrier film provided above the base substrate, and a contact hole that is formed in the interlayer dielectric film and is connected to the upper electrode of the ferroelectric capacitor.
